(19) United States
(12) Patent Application Publication
(10) Pub. No.: US 2009/0051027 A1
(43) Pub. Date: Feb. 26, 2009

(54) Method of Manufacture and Identification of Semiconductor Chip Marked For Identification with Internal Marking Indicia and Protection Thereof by Non-black Layer and Device Produced Thereby

(75) Inventor: Mou-Shiung Lin, Hsin-Chu (TW)

Correspondence Address: Mou-Shiung Lin;Science-Based Industrial Park, Room 301/302, No. 47,, Park 2nd Rd.,, Hsin-Chu, 300, TW

(73) Assignee: MEGICA CORPORATION, Hsinchu (TW)

(21) Appl. No.: 12/260,086

(22) Filed: Oct. 28, 2008

Related U.S. Application Data
(63) Continuation of application No. 09/523,990, filed on Mar. 13, 2000.

(51) Int. Cl. H01L 23/488

(52) U.S. Cl. 257/734; 257/E23.023

(57) ABSTRACT

An electronic integrated circuit has a planar front surface and a planar backsurface. Internal marking indicia identification are marked upon an marking surface on the exterior surface of the chip. The internal identification indicia on the chip surface are protected against remarking by a non-black, colored, optically transmissive layer, so the indicia are visible through the optically transmissive material. Electrical interconnection means connect to the electrical contact site through the package. There is least one electrical contact site on an exterior surface of the chip.

This application is a continuation of application Ser. No. 09/523,990, filed on Mar. 13, 2000, now pending.

### BACKGROUND OF THE INVENTION

1. Field of the Invention

This invention relates to semiconductor packages and more particularly to materials and methods employed in packaging thereof.

2. Description of Related Art

Encapsulation materials for semiconductor packages are colored black to protect the contents thereof from light. Thus X-rays must be used for the inspection after encapsulation. It is expensive to use X-ray inspection and personnel operating the inspection apparatus always need to be concerned the safety factors involved with the use of X-rays.

The continued trend toward miniaturization of electronic and electrical systems requires a reduction in the overall size of the semiconductor device packages that are employed therein. Thus, small size packages having excellent reliability, and multi-function capability are required.

U.S. Pat. No. 5,641,997 of Ohta et al. for “Plastic-Encapsulated Semiconductor Device” describes encapsulating a semiconductor device between plastic sheets. The plastic is formed of resins which have colorants. See col. 18, lines 25-Col 19, line 27. At Col. 19, lines 15-17 it is stated: “The package of EPROM needs a window permitting light irradiation such as UV rays to erase information stored in the semiconductor chip.” At Col. 19, lines 20-24, it is stated: “In the present invention, one time molding can produce an EPROM using a resin sheet in which the resin composition is transparent in a portion corresponding to the window, and in another portion the resin composition is colored to screen light.”

U.S. Pat. No. 4,300,184 of Colla for “Conformal Coating for Electrical Circuit Assemblies” shows a transparent coating over a printed circuit system including circuit conductors, resistors and transistors permitting visual inspection of the circuit as well as convenient cutting or removal of the coating for access to the circuit.

U.S. Pat. No. 5,461,545 of Leroy et al. for “Process and Device for Hermetic Encapsulation of Electronic Components” shows plastic packages which enclose electronic components which contain discrete components or integrated electronic components encapsulated in the packages, which can be mounted flat. Alternatively, the packages are have connecting lugs or pins mounted on a printed circuit board. The printed circuit board and the packages are encapsulated with from two to four organic and inorganic material layers. A first organic material layer is composed of an organic material, e.g. Parylene®, silicone, epoxy or acrylic varnish, to encapsulate the printed circuit board and previously packaged components.

A hermetic, second inorganic material layer is composed of an material such as a metal compound e.g. aluminum, silicon, zirconium, tin oxide; or a metal nitride, e.g. as silicon nitride. In an alternative embodiment a third, organic layer of a material such as Parylene® is formed with a thickness of 5-10 μm. In still another alternative, a fourth inorganic layer comprise SiO2. At Col. 4, lines 13-16, it states “Finally, since these various layers are transparent when thin, the circuit markings are visible through the layers and there is no need to reproduce them on the outer layer.” This teaches the concept of showing the external markings on a packaged electronic product through the encapsulation layer.

U.S. Pat. No. 5,479,049 of Aoki et al. for a “Solid State Image Sensor Provided with a Transparent Resin Layer Having Water Repellency and Oil Repellency and Flattening a Surface Thereof” shows a solid state image sensor device containing light sensors formed in the surface of a semiconductor. Each sensor is adapted to receive and sense light of a color selected by three different color light filters formed by three different dye colors which provide one of those colors of light to each image sensor. The structure includes an array of delicate micro lenses. The device is protected by a transparent layers including a resin layer.

### SUMMARY OF THE INVENTION

An object of this invention is to replace the process of X-ray inspection of integrated circuit chips to reduce the cost of inspection and to alleviate the concerns pertaining to safety issues.

An object is to provide internal colored markings and/or indicia on packages which cannot be scraped off and replaced by different markings and/or indicia for purposes of relabeling or to cover up the original source of a product in cases of misappropriation of products.

Another object of this invention is to replace the encapsulation material with an optically transmissive, non-black, colored or transparent material which can be colored with additives.

In accordance with this invention internal colored markings and/or internal colored indicia are printed in black or in a color on a surface of a silicon chip followed. A protection layer is formed over the internal colored markings and/or indicia and the chip. The protection layer is a clear, colored, tinted and transparent or translucent material.

The formation of the protection layer can be performed by molding, printing, dispensing and glob top, etc. A glob top dispenses the encapsulation material such as an epoxy material onto the top of IC chips during packaging thereof.

One can also print indicia such as the identity of the product and the identity of the manufacturer with numerals or a bar code, etc. on the back and/or the front of the silicon substrates of IC chips depending upon the type of packaging being employed and where the location of indicia are most readily observed by an inspector.

For example, one can use a flip-chip package and use a clear material to cover the surface-upon which the non-black, protection layer is formed over the chip.

This invention is applicable to protection and encapsulation layers used in the design of a Chip-Scale Package (“CSP”).

Acronyms for Advanced Packages

Ball grid Array
BGA Ball grid Array
CBGA Ceramic BGA
C2BGA Controlled Collapse BGA
DBGA Dimple BGA
D2BGA Die-Dimension BGA
EPBGA Enhanced PBGA
FCBGA Flip Chip in BGA
FPBGA Fine Pitch BGA
μBGA BGA (Tessera)
MBGA Metal BGA
MiniBGA FPBGA (above)
PBGA Plastic BGA
SuperBGA High-performance BGA (Amkor)
studBGA BGA with studs, or pin type leads

Bump Chip
BCC Bump Chip Carrier

TAB
TAB Tape-Automated Bonding
TBGA Tab/tape BGA

Chip-Scale Package
CSP Chip-Scale Package
MCSP Micro Chip-Scale Package

MicroStarBGA CSP (Texas Instruments)
NCSP Near Chip-Scale Package
SCSP Super CSP (Fujitsu)
TGACSP Transformed Grid Array CSP
WLA-CSP Wafer-Level Assembly-CSP

A so-called CSP (“Chip-Scale Package” or “Chip Size Package”) is on the scale of single chip and can be mounted using surface mount technologies. The CSP is produced as an individual unit, rather than in strip form.

Flat Pack

| | |
|---|---|
| QFP | Quad Flat Pack |
| BQFP | Bumped Quad Flat Pack |
| MQUAD | Enhanced QFP (Olin) |
| MetalQFP | Metal cased Quad Flat Pack |
| MQFP | Metric Quad Flat Pack |
| PQFP | Plastic Quad Flat Pack |
| LP-PQFP | Low-Profile PQFP |
| SQFP | Shrink Quad Flat Pack |
| TapeQFP | QFP with a flex Tape type substrate |
| TQFP | Thin Quad Flat Pack |
| VQFP | Very-small (fine pitch) Quad Flat Pack |

Small Outline Package

| | |
|---|---|
| SOIC | Small Outline IC (package) |
| SOJ | Small Outline package with “J” lead form |
| SOP | Small Outline Package |
| SOT | Small Outline Transistor |
| SSOP | Shrink Small Outline Package |
| TSOP | Thin Small Outline Package |
| TSSOP | Thin, Shrink Small Outline Package |
| VSOP | Very Small Outline Package |

Tape Carrier Pack

| | |
|---|---|
| TCP | Tape Carrier Pack |
| TapePak | TCP |

Leadless Chip Carrier

| | |
|---|---|
| CLCC | Ceramic Leadleass Chip-Carrier |
| PLCC | Plastic Leadless Chip Carrier |

Arrays

| | |
|---|---|
| CGA | Column Grid Array |
| LGA | Land Grid Array |

Miscellaneous

| | |
|---|---|
| C4 | Controlled Collapse Chip-Carrier |
| COL | Chip-On-Lead |
| COB/F | Chip-On-board/flex |
| LOC | Lead-On-Chip |
| PDIP | Plastic Dual in-line Package |
| SLICC | Slightly Larger than IC Carrier (Motorola) |
| WAVE | Wafer Area Vertical Expansion |

In accordance with a first aspect of this invention, a method is provided for marking an electronic integrated circuit chip having surfaces comprising the steps of forming internal marking indicia on a marking location upon an exterior surface of the chip for identification of the chip, and forming a non-black, optically transmissive material over at least the marking location on the one exterior surface of the chip.

Preferably, the non-black, optically transmissive material comprises a non-black, transparent or semi-transparent material. The non-black, optically transmissive material is used for environmental protection and handling of the silicon devices. One directs electromagnetic radiation upon the internal marking indicia through the non-black optically transmissive material. Then read the internal marking indicia in response to images of the internal marking indicia provided by reflections of the electromagnetic radiation. Preferably, the non-black, optically transmissive material comprises a colored material; and the non-black, optically transmissive material prevents remarking indicia or identification marks on the device. Alternatively, the non-black, optically transmissive material prevents remarking silicon for a semiconductor package and the optically transmissive material is a transparent material.

Preferably, the method includes the steps of directing electromagnetic radiation upon the internal marking indicia through the non-black optically transmissive material. Then the internal marking indicia are read in response to images of the internal marking indicia provided by reflections of the electromagnetic radiation.

In accordance with another aspect of this invention, the method involves forming a semiconductor, integrated circuit chip having surfaces including a planar front surface, a planar back surface and edges of the chip between the planar surfaces with at least one electrical contact site on a surface, forming internal marking indicia upon an exterior marking portion of a surface of the chip for identification of the chip, and forming a non-black layer covering the exterior surface of the chip at least at the exterior marking portion thereof, the non-black layer being composed, of a colored, optically transmissive material preventing remarking the indicia on the exterior marking surface of the chip, whereby the indicia are visible through the non-black layer.

In accordance with another aspect of this invention, a chip has surfaces form a non-black, colored material layer over at least an exterior surface of the chip wherein the particular color indicates the identification of the chip.

Alternatively, form internal marking indicia on a marking location upon an exterior surface of the chip, and form a non-black, optically transparent material colored with a particular color over at least the marking location on that exterior surface of the chip wherein the particular color together with the marking indicia represents identification of the chip.

In accordance with another aspect of this invention, an electronic integrated circuit chip has exterior surfaces, internal marking indicia formed on a marking location upon an exterior surface of the chip for identification of the chip, and a non-black, optically transmissive material formed over at least the marking location on the one exterior surface of the chip.

The device has non-black, optically transmissive material comprises a non-black, transparent or semi-transparent material; the non-black, optically transmissive material comprises a colored material; and/or the non-black, optically transmissive material prevents remarking indicia or identification marks on the device.

The non-black, optically transmissive material prevents remarking silicon for a semiconductor package and the optically transmissive material is a transparent material.

Preferably, illumination means are provided for directing electromagnetic radiation upon the internal marking indicia through the non-black optically transmissive material and reading means are provided for reading the internal marking indicia in response to images of the internal marking indicia provided by reflections of the electromagnetic radiation.

Preferably an electronic integrated circuit includes a semiconductor, integrated circuit chip having surfaces including a planar front surface, a planar back surface and edges of the chip between the planar surfaces with at least one electrical contact site on a surface. Indicia are marked upon an exterior marking portion of a surface of the chip for identification of the chip. A non-black layer covers the exterior surface of the chip at least at the exterior marking portion thereof. The non-black layer is composed, of a colored, optically transmissive material preventing remarking the indicia on the exterior marking surface of the chip, and the indicia being visible through the non-black layer.

Illumination means are provided for directing electromagnetic radiation upon the internal marking indicia through the non-black optically transmissive material. Reading means are provided for reading the internal marking indicia in response to images of the internal marking indicia provided by reflections of the electromagnetic radiation.

The chip with a non-black, colored material layer over at least an exterior surface of the chip wherein the particular color indicates the identification of the chip.

Internal marking indicia formed on a marking location upon an exterior surface of the chip, and a non-black, optically transparent material colored with a particular color is formed over at least the marking location on that exterior surface of the chip wherein the particular color together with the marking indicia represents identification of the chip.

### BRIEF DESCRIPTION OF THE DRAWINGS

The foregoing and other aspects and advantages of this invention are explained and described below with reference to the accompanying drawings, in which:

FIGS. 1 to 6 show Chip-Scale Package (CSP) related structures in accordance with this invention.

FIG. 7 is a schematic cross-sectional view of an example of conventional CSP of the type manufactured by Tessera.

FIG. 8 is a cut-away perspective view of another example of conventional CSP of the type manufactured by Mitsubishi.

FIG. 9 is an exploded top perspective view of an attachment of a chip to a TAB tape.

FIG. 10 is a perspective view depicting the encapsulated package of FIG. 9.

FIG. 11 is a perspective view illustrating the separation of an individual chip from the lead frame strip.

FIG. 12 is a sectional view of the individual chip of FIG. 11, taken along the line 12-12 in FIG. 1.

FIG. 13 is a perspective view illustrating the separation of an individual chip from a lead frame strip.

FIG. 14 is a sectional view of the individual chip of FIG. 13 taken along the line 14-14 in FIG. 1.

FIGS. 15 to 18 show tape-carrier package (TCP) devices.

FIGS. 19 to 22 are lead frame type devices.

FIG. 23 shows another tape-carrier package (TCP) type device.

FIG. 24 shows a lead frame type device.

FIG. 25 shows a TAB type package.

FIG. 26 shows a LOC (Lead-On-Chip) type package.

FIGS. 27-30 show wafer level packaging structures in accordance with this invention.

FIG. 31 shows a chip marked with a mark applied to the exterior surface of a chip.

FIG. 32 shows a chip marked with internal marking indicia protected by an intermediate non-black layer in accordance with one embodiment of this invention.

FIG. 33 shows a chip marked with internal marking indicia protected by an intermediate non-black layer in accordance with another embodiment of this invention.

FIG. 34 is a flow chart for a method of marking, protecting markings and inspecting markings on a chip in accordance with this invention in accordance with FIG. 32.

FIG. 35 is a flow chart for a method of marking, protecting markings, and inspecting markings on a flip-chip in accordance with this invention in accordance with FIG. 33.

FIG. 36 shows a prior art flip chip marked with external markings.

FIG. 37 shows a flip chip marked with internal markings, in accordance with this invention.

FIG. 38 shows a CSP package with a wire bonded chip marked with internal markings, in accordance with this invention.

### DESCRIPTION OF THE PREFERRED EMBODIMENT

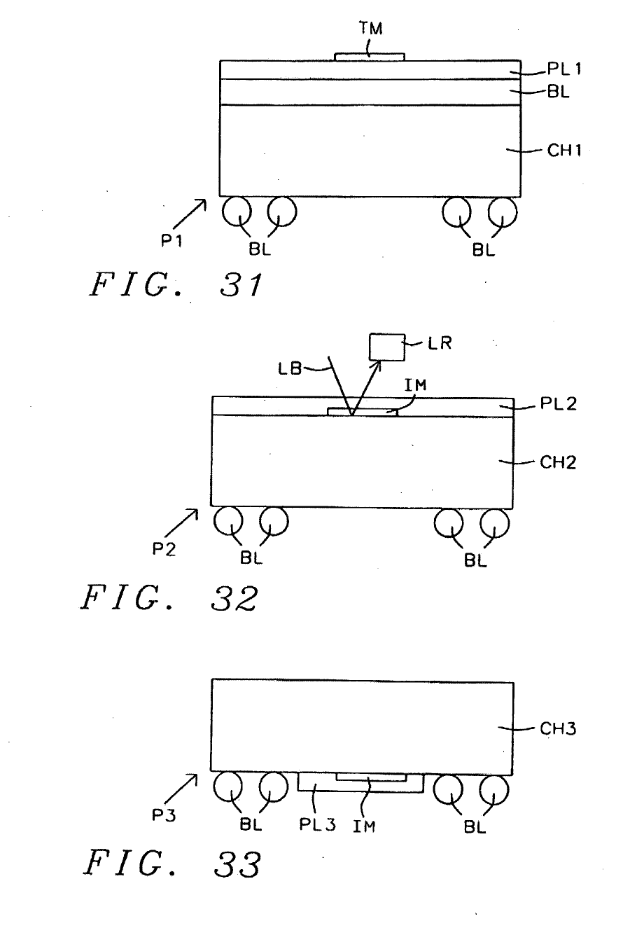

FIG. 31 shows a first way of marking a package P1. Package P1 includes a chip CH1, a black layer BL, a non-black protection layer PL1 and externally applied indicia comprising a top mark TM. The black layer BL is formed on the top surface of the chip CH1. The non-black, protection layer PL3 is formed on the top surface of the black layer BL. The black layer BL may be pigmented by impregnating a molding compound with carbon to make the black layer BL light absorbing. A laser-written, opaque top mark TM is formed on the exterior of the non-black, protection layer PL. There is a problem with an externally-applied indicia comprising top mark TM which is easily remarked since the laser mark TM is on the top external surface of the chip package P1. Balls BL of a Ball Grid Array (BGA) are provided for electrical connection of circuits on the chip CH1 and mechanical connection of the chip CH1 to a connection board (not shown) is shown on the lower surface of the chip CH1.

FIG. 32 shows a type of marking in accordance with this invention for a flip-chip chip scale package P2. In this case the difference is that the package P2 comprising a chip CH2 has internal marking indicia IM formed on the top surface thereof. In this case the internal marking indicia IM are protected from damage or remarking since chip CH2 is covered, at least in part, by a non-black, protection layer PL2. The protection layer PL2 is formed directly on the top surface (back surface) of the chip CH2 and on top of the internal marking indicia IM. Note that the BL solder balls BL are attached to the active device surface of the chip CH2.

In the case of FIG. 32, the internal marking indicia IM can be placed on the upper surface of the chip CH2 as seen in FIG. 32. Thus a laser code reader can read the marking through the transparent protection layer PL2. The layer PL2 comprises a non-black, colored material layer covering at least an exterior surface of the chip CH2 wherein the particular color of layer PL2 indicates the identification of the chip CH2. Again, the internal marking indicia IM are formed on the marking location upon the exterior surface of the chip CH2, and the non-black, optically transparent protection layer PL2 is formed of a material colored with a particular color, whereby the particular color together with the marking indicia represents identification of the chip CH2.

FIG. 33 shows an alternative type of marking in accordance with this invention. In this case the difference is that the package P2 comprising a flip-chip (face down) CH3 has internal marking indicia IM formed on the bottom surface (that is the active device surface) thereof. In this case the internal marking indicia IM are protected from damage or remarking since chip CH3 is covered, at least in part, by a non-black, protection layer PL3 between elements of the BGA balls BL. Protection layer PL3 is formed directly on the lower surface (as seen in FIG. 33) of the flip-chip CH3 and on top of the internal marking indicia IM. Some chips are sensitive to light. This embodiment protects the light sensitive surface of the flip-chip CH3 from exposure to light leakage since the uncovered surface is facing the lower packaging element (not shown) which will protect the light sensitive surface of flip-chip CH3 from light.

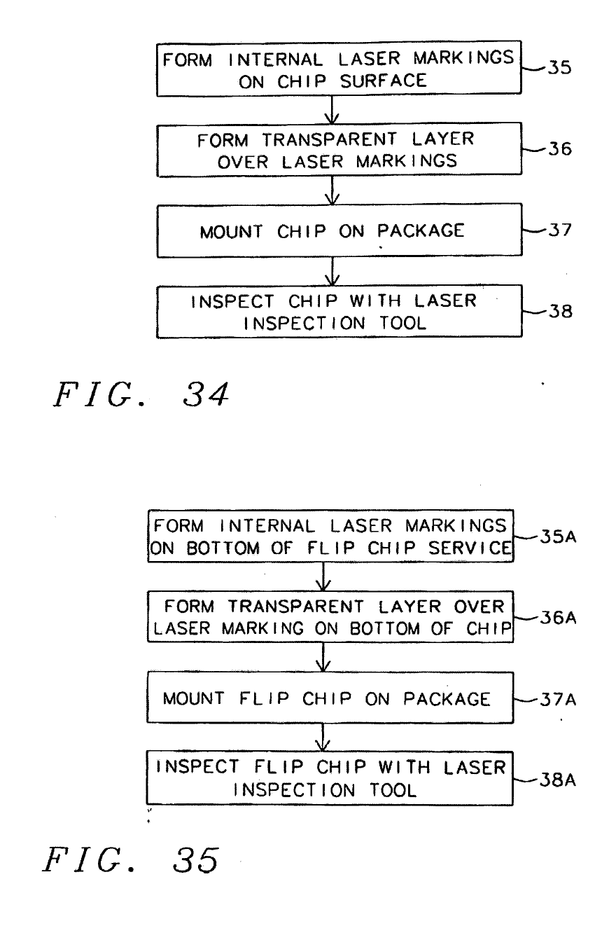

FIG. 34 is a flow chart for the method of this invention in accordance with FIG. 32 for marking, protecting markings and inspecting markings on a chip.

Referring to FIG. 34, it should be understood that steps 35 and 36 are always done on the wafer level and then the chips are diced for later mounting of the chip onto the package.

The first step 35 is to form internal identification indicia on a surface of chip CH2, in this case it is the top surface of chip CH2, in accordance with FIG. 32. The internal marking indicia IM are preferably laser readable markings IM formed on a selected surface of the chip CH2 which in this case is the top surface.

In step 36, the internal marking indicia IM are protected from damage or remarking since it is covered, at least in part, by a non-black, protection layer PL2. Protection layer PL2 is formed directly to cover the top surface of the chip CH2, thereby covering the internal marking indicia IM.

In step 37, the chip CH2 with the internal marking indicia IM and the protection layer PL2 is mounted on the package.

In step 38, the chip CH2 is inspected with a laser inspection tool.

FIG. 35 is a flow chart for the method of this invention in accordance with FIG. 33 for marking, protecting markings, and inspecting markings on a flip-chip.

The first step 35A is to form internal identification indicia on a surface of chip CH2, in this case it is the bottom surface of flip-chip CH3, in accordance with FIG. 33. The internal marking indicia IM are preferably laser readable markings IM formed on a selected surface of the chip CH3 which in this case is the bottom surface.

In step 36A, the internal marking indicia IM are protected from damage or remarking since chip CH3 is covered, at least in part, by a non-black, protection layer PL3. Protection layer PL3 is formed directly on the bottom surface of the chip CH3 and covering of the internal marking indicia IM.

In step 37A, the chip CH3 with the internal marking indicia IM and the protection layer PL2 is mounted on the package.

In step 38A, the chip CH3 is inspected with a laser inspection tool.

This invention makes it possible to replace the process of X-ray inspection of chips by use of optical microscopy so that the cost of inspection can be reduced and that the concern pertaining to safety issues can be alleviated.

A feature of the present invention is to provide encapsulation material pigmented with pigments other than opaque black pigments to other light transmissive pigments and colors by providing additives which are impregnated or otherwise added to the encapsulation material.

The invention includes printing or laser marking and or forming a set of colored indicia on silicon chip front/back and use clear encapsulation material.

The encapsulation method can be molding, printing, dispensing and glob top, etc. While the protection layers PL2 and PL3 are shown covering only the surfaces upon which the internal marking indicia IM are formed, the protection layers can cover most of the device or the entire device or different types of protection layers can be employed upon different surfaces of the chip.

While the connectors shown are ball grid arrays of elements BL in FIGS. 32 and 33, the various different types of embodiments which can incorporate the use of an internal marking indicia IM covered by a protection layer are shown in FIGS. 1-30. The internal marking indicia IM can be located anywhere on the exterior of the chip as shown in FIGS. 32 and 33 with a protection layer (e.g. PL2 or PL3) formed thereover as will be well understood by those skilled in the art.

Flexible Interposers

FIG. 1 shows a compression bonded Chip-Scale Package (CSP) P with a flexible interposer I1 upon which a face-down, integrated circuit chip C with planar top and bottom surfaces is supported on the lower planar surface thereof by gold or solder plated bumps PB which are bonded to lands L on the top surface of the interposer I1. On the base of the interposer is carried a conventional Ball Grid Array (BGA) of balls B.

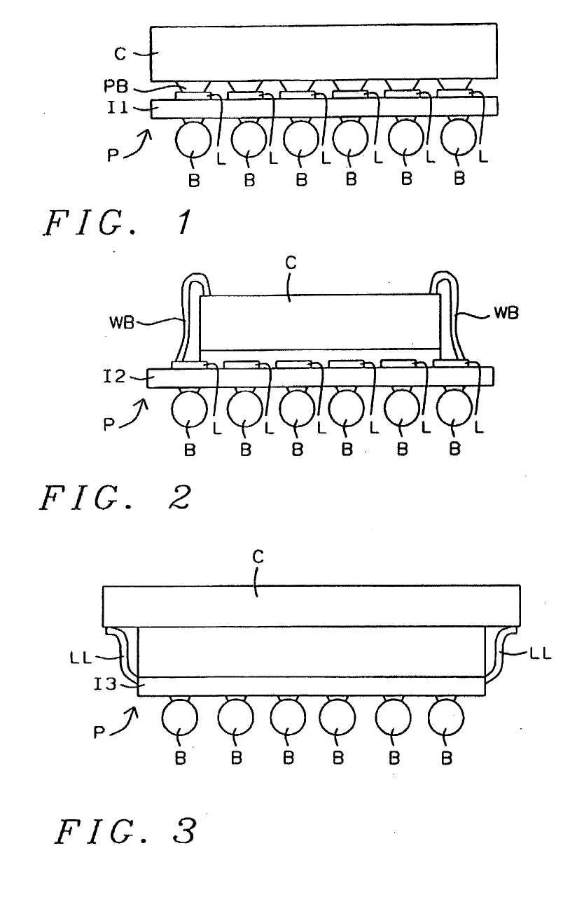

FIG. 2 shows a wire bonded CSP P with a flexible interposer I2 to which a chip C is connected by wire bonds WB. In this case the chip C is face-up so the wire bonds WB connect to terminals on the top surface of the chip C, i.e. the face thereof. The base of the interposer I2 carries a BGA of balls B.

FIG. 3. shows a Tessera type of TAB bonded package P known as the μBGA with leads LL connected between the terminals on a face-down chip C and lands (not shown) on the top surface of the thin interposer I3 which again carries a BGA of balls B.

Rigid Substrate

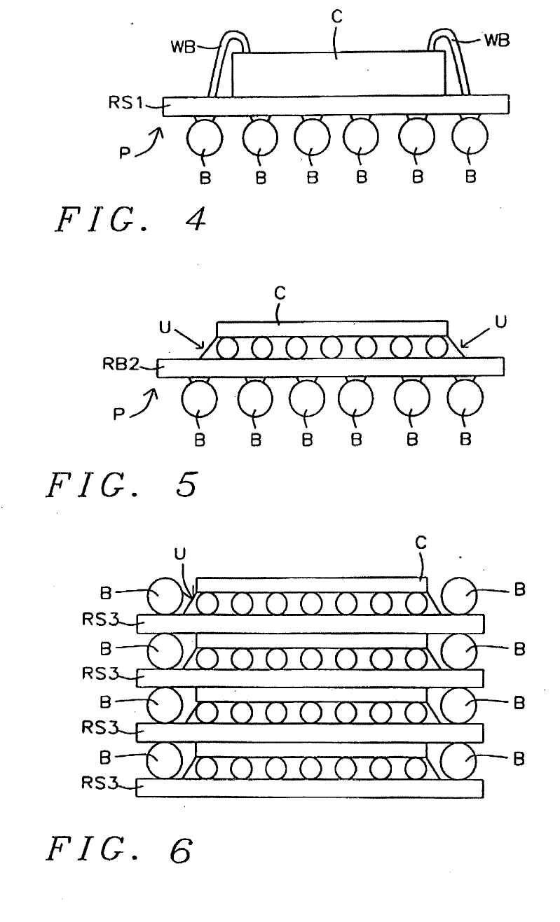

FIG. 4 shows a face-up chip C supported by a CSP P which includes a rigid substrate RS which has lands (not shown) connected by wire bonds WB to the terminals on the chip C. The rigid substrate RS1 carries a BGA of balls B.

FIG. 5 shows a the (face-down) arrangement in which chip face-down chip C is mounted on an under-filled Ball Grid Array U on a polytetrafluoroethylene (Teflon®) type of circuit board RS2. Board RS2 can be a laminate or a BT resin substrate. Large balls B are placed in the BGA of balls B on the base of the circuit board RS2.

FIG. 6 shows a modification of the device of FIG. 5 in which the large balls B are placed on the same side as the rigid circuit board RS3 as the, face-down chips C, for stacking the boards RS3.

FIG. 7 is a schematic cross-sectional view of a conventional Chip-Scale Package (CSP) 100 of the type manufactured by Tessera Corp. The CSP 100 has bonding pads 12 on the bottom surface of the chip 19 that are electrically connected to respective ones of the corresponding flexible patterns 20. Insulating polyimide film 40 is bonded to the bottom surface of flexible patterns 20. The polyimide film 40 has via holes coated with a conductive material on their inner wall, through which the flexible patterns 20 are electrically connected to solder bumps 60. An elastomer 30 is interposed between the flexible patterns 20 and the parts of the bottom surface of the chip 10 where no bonding pads are formed. The chip 19 is immobilized by a handling ring 50.

This type of package is basically a micro-BGA or -BGA (Ball Grid Array) package using a the interconnection technology. This structure is advantageous in that it can be subjected to various tests such as burn-in tests, as well as allowing for high density mounting and efficient heat dissipation.

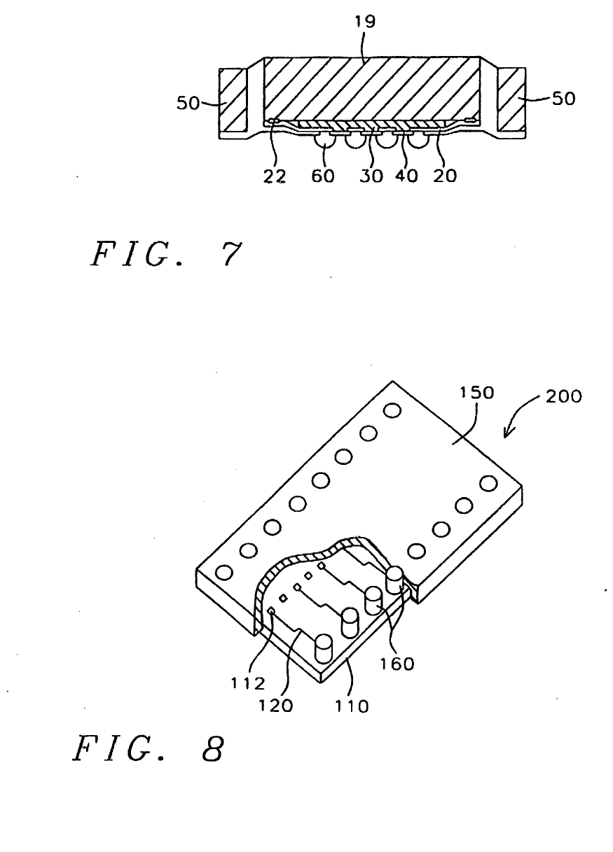

FIG. 8 is a cut-away perspective view of another example of conventional CSP of the type developed by Mitsubishi Corp. The CSP 200 has bonding pads 112 formed on the central part of the upper surface of chip 110 that are electrically connected to respective ones of the corresponding solder bumps 160 via circuit patterns 120 on the upper surface of the chip 110. The chip 110, circuit patterns 120 and electrical interconnections 112 are encapsulated with a molding compound 150 to provide protection from the external environment. The solder bumps 160 are exposed through the surface of the molding compound 150.

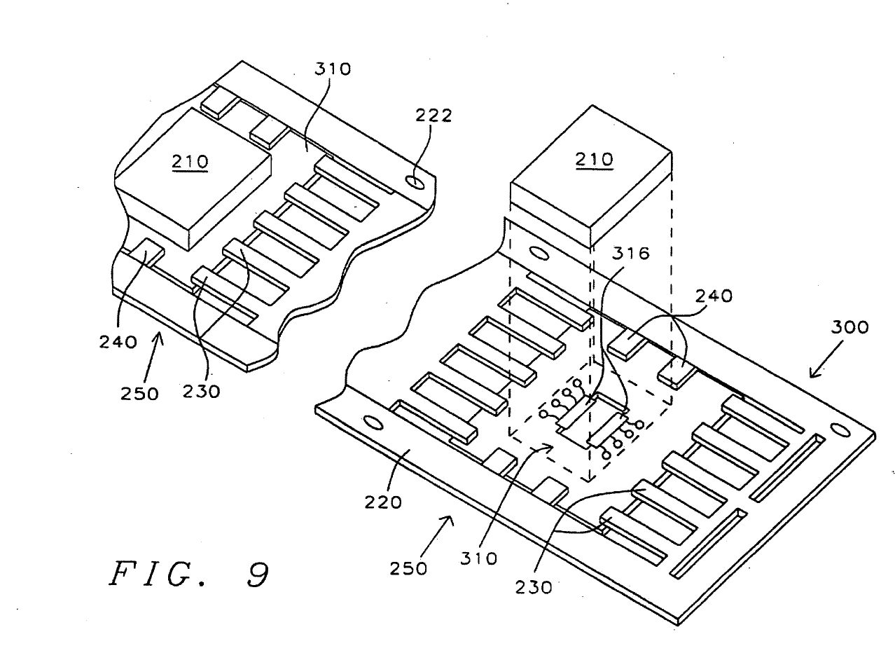

FIG. 9 is a perspective view depicting a lead frame strip with a plurality of TAB (Tape Automated Bonding) tapes showing an embodiment of the present invention. A set of lead frames 250 which are part of a lead frame strip 300 each have a TAB tape 310 bonded thereto. Patterned TAB tapes 310 are attached to a plurality of LOC (Lead-on-Chip) lead frames 250. The TAB tapes 310 are bonded to a bottom surface of spaced parallel leads 230 and a bottom surface of tie bars 240 of each of the respective corresponding lead frames 250. The lead frame strip 300 comprises a pair of parallel side rails 220 having a plurality of indexing holes 222 spaced at a designated distance, with the plurality of lead frames 250 formed between and along the side rails 220.

The indexing holes 222 of the side rails 220 mate with pins of a lead frame transferring rail of the semiconductor device package assembly system for indexing and moving the lead frame strip 300. As shown in FIG. 9, the LOC type lead frame 250 has two opposing rows of a plurality of, for example, five leads 230. The TAB tape 310 will be disposed in the space defined between the rows of the leads 230.

TAB tape 310 is comprised of a polyimide base tape having an adhesive at both its upper and lower surfaces and an elongated slot formed in a central portion therein. As shown in U.S. Pat. No. 5,951,804, contact leads are formed in a pair of opposing rows on the upper surface of the base tape. Each of the contact leads has one end extending toward the center of the elongated slot. Each row of contact leads is bonded to a double-sided adhesive, for example, polyimide tape. On the base tape, a plurality of via holes are formed in two rows, outwardly of the rows of contact leads. The number of via holes equals that of the contact leads. External connection terminals, for example, solder balls, are mounted on and electrically connected to the via holes.

TAB tapes 310 are bonded to respective ones of the corresponding lead frames 250 in the lead frame strip 300 as follows: a plurality of TAB tapes 310 are aligned below the lead frame strip 300 so that each TAB tape 310 can be fitted to a corresponding lead frame 250. Multiple bondings between the plurality of TAB tapes 310 and the respective corresponding plurality of lead frames 250 are simultaneously carried out by either lifting the TAB tapes 310 or lowering the lead frame strip 300 by using a lifting apparatus (not shown).

FIG. 9 is a perspective view of an attachment of a chip 210 to the TAB tape 310 with the active surface of the chips 210 attached to respect I=ve pairs of corresponding polyimide tapes of the TAB 310. Then, bonding pads formed on the central part of the active surface of the chip 210 are electrically connected to respective corresponding contact leads of the TAB tape 310 via conventional bonding wires. Wire electrical connections are attached through the elongated slot of the base tapes.

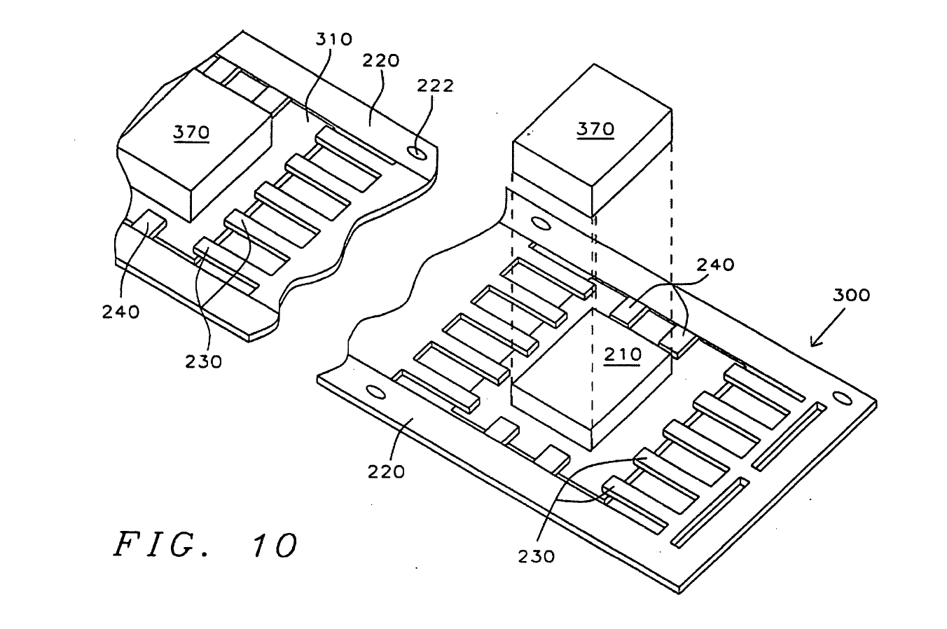

FIG. 10 is a perspective view depicting an encapsulated package of FIG. 9. The top surface of base tapes and chips 210 are encapsulated with epoxy molding resin to produce individual chip packages 370. Electrical connections, not shown on the bottom of the chips 210 are encapsulated by filling an elongated slot with a liquid resin 360 seen in FIGS. 1 and 12. The top surfaces of the base tapes and chips 210 are encapsulated with epoxy molding resin to produce individual chip packages 370. The order of liquid resin and epoxy molding encapsulation steps may be exchanged, or both steps may be carried out simultaneously.

FIG. 11 is a perspective view illustrating the separation of an individual chip package 400 from the lead frame strip 300.

FIG. 12 is a sectional view of an individual Chip Size Package (CSP) 400, taken along the line 31-31 in FIG. 1. An individual CSP 400 is separated from the lead frame strip 300 by cutting the base tapes 312, that are joined to lead frame strip 300, around the area forming package body 370, using a cutting means such as a punch to produce an individual CSP 400. Each individual CSP 400 is then subjected to various reliability tests prior to shipment. In the orientation shown, the active surface of chip 210 is bonded to the lower surface of adhesive polyimide tapes 316. Bonding pads 348 formed on the central part of chip 210 are electrically connected to respective corresponding contacts 315 via wires 350. The contact leads 315 are again electrically connected respectively to corresponding via holes 318 through circuit patterns 311. The via holes 318 are electrically connected respectively to corresponding external connection terminal balls 313. Solder paste 317 may be applied on the upper surface of the base tape 312 around the via holes 318 to easily and securely mount connection terminal balls 313. The inner walls of via holes 318 are covered with a conductive coating material 318a for electrical connections. Note that the bonding pads 348 of chip 210, contact leads 315, circuit patterns 311, via holes 318 and external connection terminal balls 313 are thus electrically interconnected.

To protect the chip from the external environment the liquid resin 360 is applied to the elongated slot 314 to protect the electrical connections as shown in FIG. 12. The height of molded part 360 should be lower than that of external contact terminal balls 313. If the height of the molding part 360 is greater than that of external contact terminal balls 313, mount failures may occur and electrical connections may be damaged by the external pressure on the molding part 360 when the package 400 is mounted on electrical devices such as a printed circuit board. In a final step, the chips and the surface of base tapes 312 are encapsulated with an epoxy resin to produce an individual package.

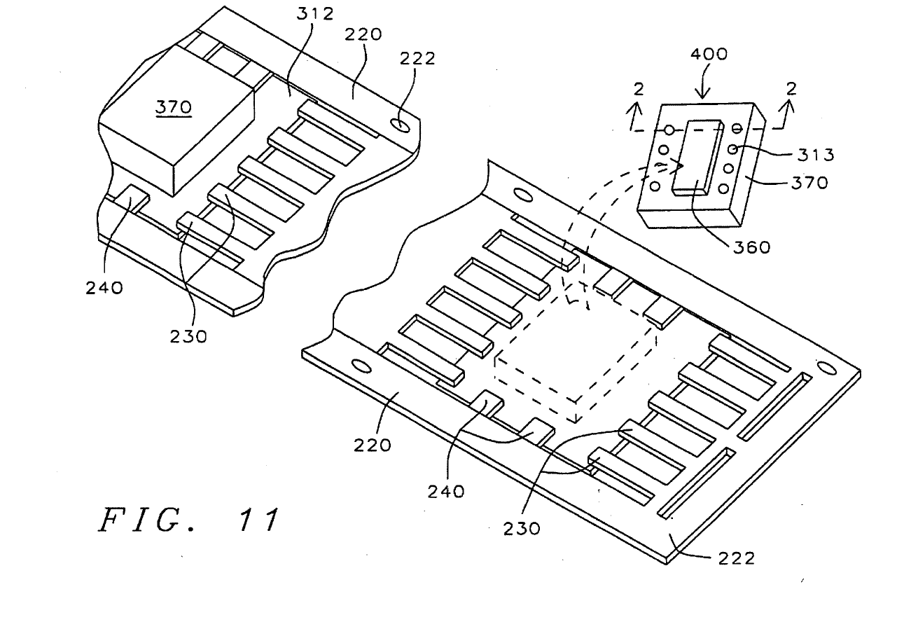

FIG. 13 is a perspective view depicting a lead frame strip with a plurality of TAB tapes according to another embodiment of the present invention. One of a pair of individual CSP's 600 is shown separated from the lead frame strip 500. Patterned TAB tapes are attached to lead frame strip 500 having a plurality of LOC (Lead-on-Chip) lead frames 450. TAB tapes are bonded to a bottom surface of spaced parallel leads 430 and a bottom surface of tie bars 440 of each of the respective corresponding lead frames 450. The lead frame strip 500 comprises a pair of parallel side rails 420 having a plurality of indexing holes 422 spaced at a designated distance, with the plurality of lead frames 450 formed between and along the side rails 420.

The indexing holes 422 of the side rails 420 mate with pins of a lead frame transferring rail of the semiconductor device package assembly system for indexing and moving the lead frame strip 500. As shown in FIG. 13, the LOC type lead frame 450 has two opposing rows of a plurality of, for example, five leads 430. The TAB tape will be disposed in the space defined between the rows of the leads 430.

Referring to FIGS. 13 and 14, TAB tape is comprised of a polyimide base tape 512 having an adhesive at both its upper and lower surfaces. A pair of elongated slots are formed at opposing peripheral sides of base tape 512. A plurality of contact leads, for example four, are formed in a pair of opposing rows on the upper surface of the base tape 512. One end of each of the contact leads 515 in each row extends toward the center of the respective adjacent elongated slot. Each row of contact leads 515 is bonded to a double-sided adhesive, for example, polyimide tape 516 as shown in FIG. 14.

On the base tape 512, a plurality of via holes 518 are formed in two rows, inwardly of the rows of contact leads 515. The number of via holes 518 equals that of the contact leads 515. The via holes 518 may be formed by punching or etching so as to have a inner diameter of 3 mil to 10 mil (0.008 mm to 0.03 mm). Inner walls of the via holes 518 are covered with a conductive coating 518a made from, for example, gold or solder. The coating 518a may be formed using a non-electrolytic plating method. External connection terminals 513, for example, solder balls, are mounted on and electrically connected to the via holes 518.

The via holes 518 may be are tapered so that its upper inner diameter is greater than the lower inner diameter. The reliability of the final package is thus improved by increasing the contact area of the external connection terminal 513 with the via hole 518. Solder paste 517 is applied on the upper surface of the base tape 512 around the via holes 518 for safe and easy mounting of external connection terminals 513 on via holes 518.

Via holes 518 are electrically connected to one end of respective ones of the corresponding contact leads 515 via circuits patterns 511. Accordingly, contact leads 515, circuit patterns 511, via holes 518 and external connection terminals 513 are electrically interconnected.

TAB tapes are bonded to respective of the corresponding lead frames 450 in the lead frame strip 500 as follows: a plurality of TAB tapes are aligned below the lead frame strip 500 so that each TAB tape can be fitted to a corresponding lead frame 450. Multiple bondings between the plurality of TAB tapes and the respective corresponding plurality of lead frames 450 are simultaneously carried out by either lifting the TAB tapes or lowering the lead frame strip 500 by using a lifting apparatus (not shown).

The active surface of chip 410 is attached to respective pairs of corresponding polyimide tapes 516 of the TAB tape. Then, bonding pads formed on each side of the active surface of the chip 410 are electrically connected to respective corresponding contact leads 515 of the TAB tape via bonding wires 550. The wire electrical connections are attached through elongated slots of the base tapes 512.

On the bottom of the device of FIG. 13 are the conventional electrical connections which are encapsulated by filling the elongated slots with a liquid resin 560. Further, the top surface of base tapes 512 and chips 410 are encapsulated with epoxy molding resin to produce individual chip packages 570. The order of liquid resin and epoxy molding encapsulation steps may be exchanged, or both steps may be carried out simultaneously.

FIG. 14 is a sectional view of an individual CSP 600, taken along the line 22-22 in FIG. 13. The individual CSP 600 is separated from a lead frame strip 500 by cutting the base tapes 512, that are joined to lead frame strip 500, around the area forming package body 570, using a cutting means such as a punch to produce each individual CSP 600. Each individual CSP 600 is then subjected to various reliability tests prior to shipment.

A cross section of a CSP 600 according to the present invention is shown in FIG. 14. In the orientation shown, the active surface of chip 410 is bonded to the lower surface of adhesive polyimide tapes 516. Bonding pads 448 formed on the side portions of chip 410 are electrically connected to respective of corresponding contact leads 515 via wires 550. The contact leads 515 are again electrically connected to respective of corresponding via holes 518 through circuit patterns 511. The via holes 518 are electrically connected to respective of corresponding external connection terminals 513. Solder pastes 517 may be applied on the upper surface of the base tape 512 around the via holes 518 to easily and securely mount connection terminals 513. The inner walls of via holes 518 are covered with a conductive coating material 518a for electrical connections. Note that the bonding pads 448 of chip 410, contact leads 515, circuit patterns 511, via holes 518 and external connection terminals 513 are thus electrically interconnected.

To protect the chip from the external environment a liquid resin 560 is applied to the elongated slots 514 to protect the electrical connections as shown in FIG. 14. The height of molded part 560 should be lower than that of external contact terminal 513. If the height of the molding part 560 is greater than that of external contact terminals 513, mount failures may occur and electrical connections may be damaged by the external pressure on the molding part 560 when the package 600 is mounted on electrical devices such as a printed circuit board. In a final step, the chips 410 and the lower surface of base tapes 512 are encapsulated with an epoxy resin to produce an individual package.

Some possible arrangements of chip packages adapted for use in accordance with this invention are shown in FIGS. 15-24.

The semiconductor devices in FIGS. 15 to 18 and FIG. 23 are tape carrier package (TCP) type devices. The pad (not illustrated) on the active surface of a semiconductor chip 5 is connected to a frame 7 (polyimide film carrier) through a bump 4 and a lead 3. Chip 5, bump 4, and lead 3 are encapsulated in the resin composition, which is composed of a first resin composition 12 having a high concentration of a filler and a second resin composition 13 having a low concentration of a filler.

In FIG. 15, first resin composition 12 is placed on the bottom surface of chip 5, and over the active surface of chip 5. In the region of lead 3 that includes the pad and bump 4, the resin is composed of a second resin composition 13.

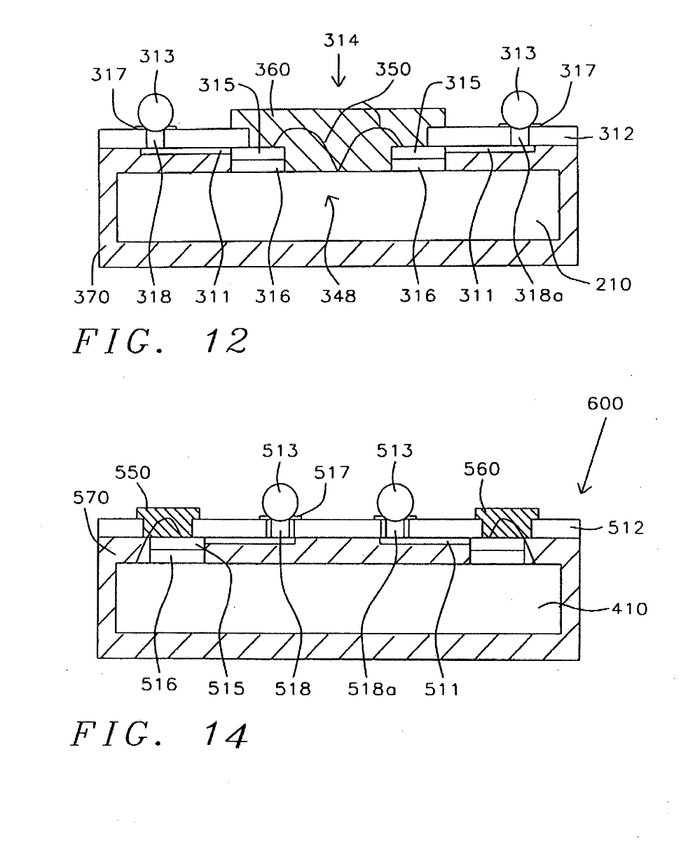

In FIG. 16, first resin composition 12 is extended to an edge of an encapsulant.

In FIG. 17, first resin composition 12 is placed on the active surface. However, the region thereof is inside of a pad region.

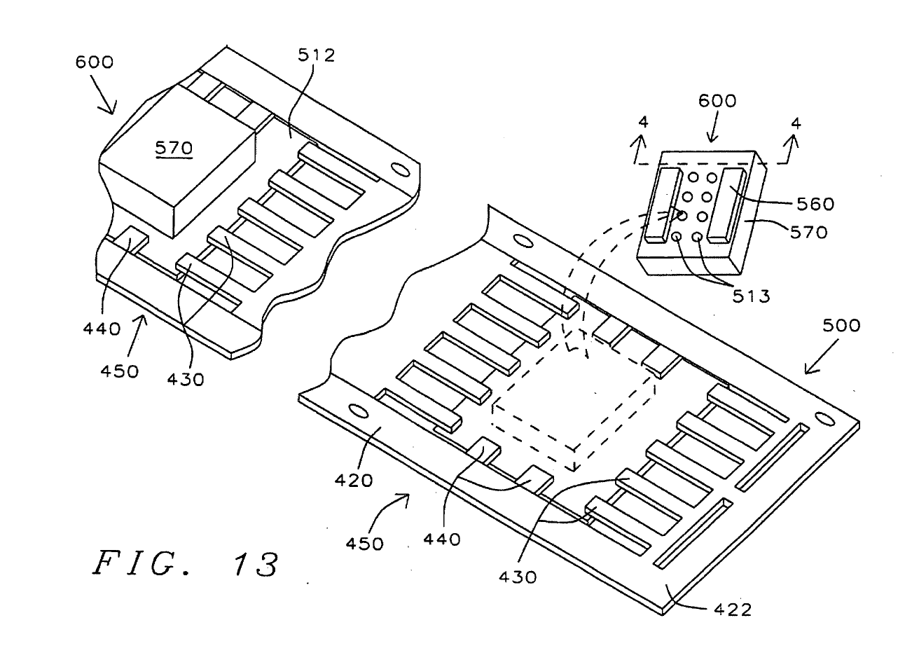

In FIG. 18, first resin composition 12 on the bottom surface of FIG. 29 is omitted.

The semiconductor devices in FIGS. 19 to 23 are lead frame type devices. A lead frame is composed of a portion of a die pad 10 and a portion of a lead 11. A semiconductor chip 5 is fixed on die pad 10 at a bottom surface and a pad (not illustrated) on an active surface of chip 5 is connected to the lead 11 through a wire 3. First resin composition 12 is placed below the die pad 10. Wire 3 is covered with the second resin composition 13.

In FIG. 19, first resin composition 12 on the active surface is inside of the pad region.

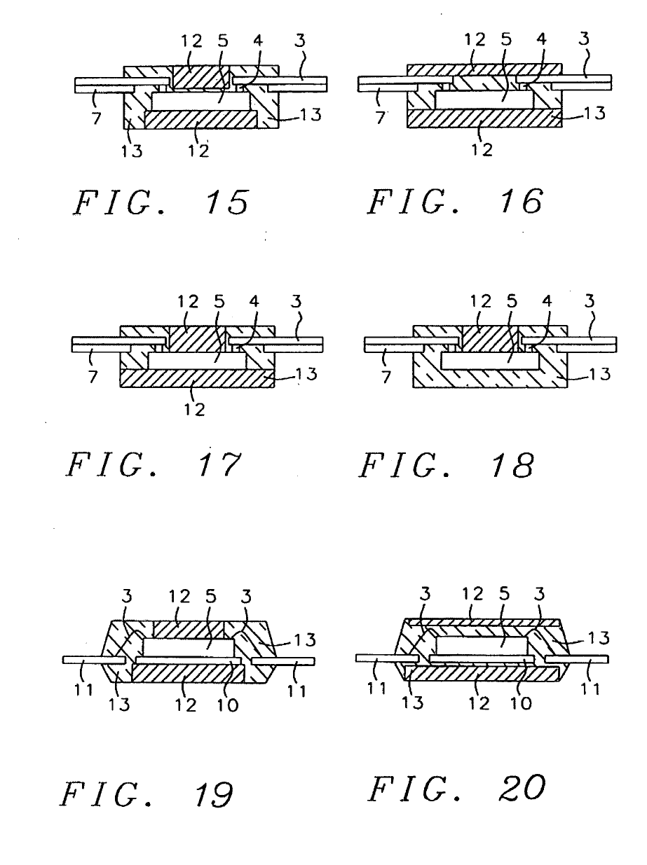

In FIG. 20, first resin composition 12 is over and below chip 5 and is extended to an edge of an encapsulant. In other words, a mass of second resin composition 13 including chip 5 and wire 3 is sandwiched within a resin plate of first resin composition 12.

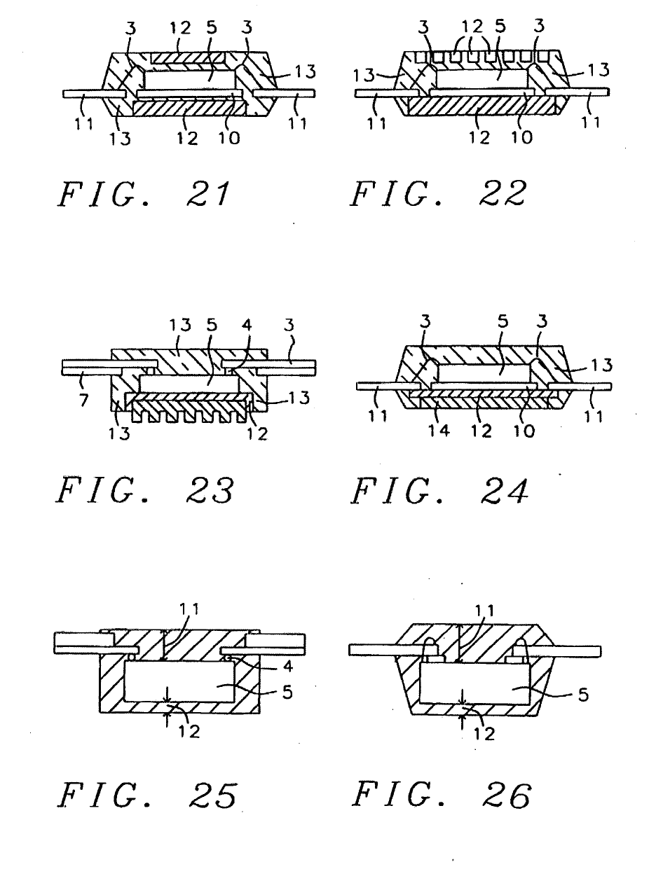

In FIG. 21, the area of first resin composition 12 is limited to a size about equal to the chip size.

In FIG. 22, an upper side first resin composition 12 is divided and a lower side first resin composition is under chip 5 and lead 11. A heat spreader plate 14, 15 of metal, such as aluminum or copper, aluminum nitride, and the like, can be placed on the encapsulant.

In FIGS. 23 and 24, radiator plate 15 is under upper first resin composition 12. The radiator plate is preferably on first resin composition 12, which has a thermal conductivity.

There is a possibility that a thermal expansivity, an elastic modulus, and a thickness of the encapsulating layer are different between the upper side of the chip (the active side) and the lower side of the chip (the bottom side).

FIG. 25 shows a TAB type package. The thickness of the encapsulant of one side (t1) adjacent to the active surface, is different from that of another side (t2) which is adjacent to the bottom surface.

FIG. 26 shows a LOC (Lead On Chip) type package.

Wafer Level Packaging

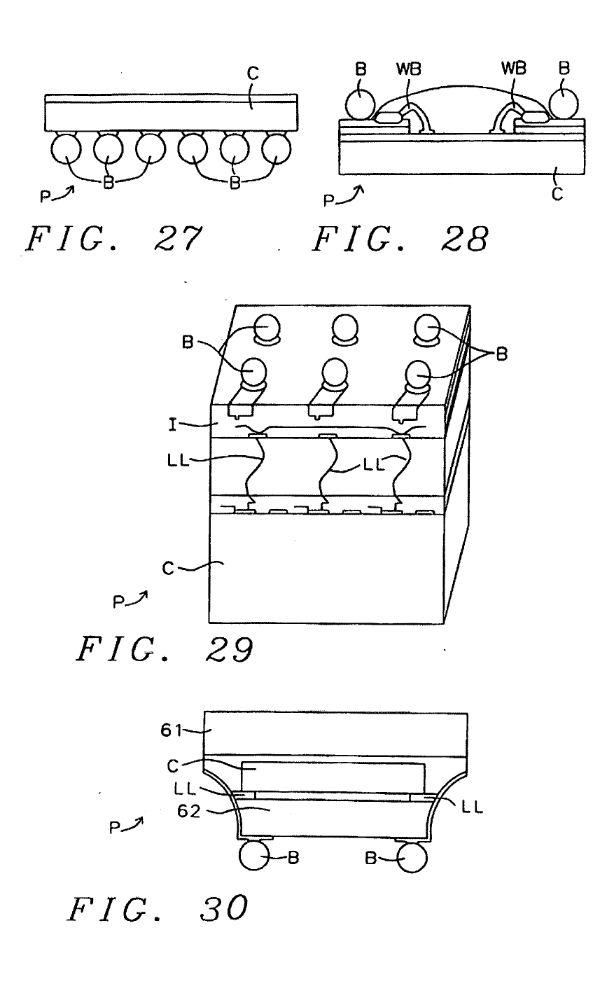

FIG. 27 shows an example of wafer level package P with a the arrangement with a redistribution layer with a chip C, and a BGA of balls B bonded to the face of the chip C.

FIG. 28 shows a BGA package P with custom lead frames with wire bond WB connections to the top of face-up chip C on which the balls B are bonded to the face of the chip C.

FIG. 29 shows a chip C connected to a flexible interposer I which carries a ball grid array B on its surface. The interposer I is connected to chip by compliant wire bond lead lines LL between the chip C and the flexible interposer I.

FIG. 30 shows a chip C encased between glass plates G1 and G2 or the equivalent with wire bond lead lines LL secured to the face down chip C.

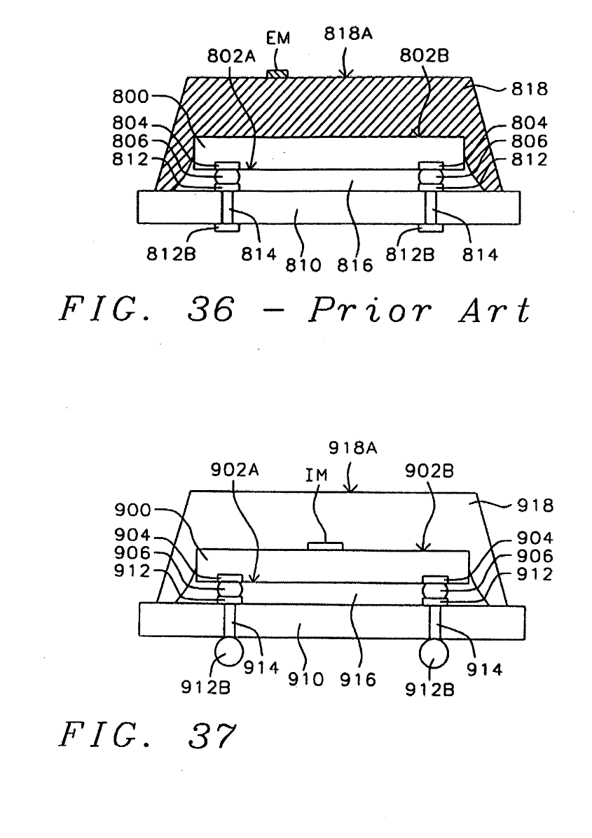

FIG. 36 shows a prior art flip chip 800 marked with external markings EM. The front surface 802A of chip 800 is formed on the bottom thereof. Mounting pads 804 of chip 800 are connected to solder elements 806 on substrate 808 which are connected by vias 814 to pads 812B on the base of substrate 808. Between the bottom (front surface 802A and the substrate 808 is underfill material 816. The back surface 802B of the chip 800 is on the top thereof. A cover 818 formed of black, optically opaque material, is formed over the back surface 802B and on the edges and portions of the sidewalls of chip 800 reaching down to be sealed with the top surface of the substrate 808. An external mark EM is formed on the exterior surface 818A of the black cover 818.

FIG. 37 shows a flip chip 900 marked with internal markings IM, in accordance with this invention. The front surface 902A of chip 900 is formed on the bottom of chip 900. Mounting pads 904 of chip 900 are connected to solder elements 906 on substrate 908 which are connected by vias 914 to ball grid array 912B on the base of substrate 908. Between the bottom (front surface 902A and the substrate 908 is underfill material 916. The back surface 902B of the chip 900 is on the top thereof. An internal mark IM is formed on the back (top surface) of the chip 800 instead of the exterior surface of the cover 918 which is formed over the chip 900. The cover 918 is composed of transparent material which is optically transparent is formed over the back surface 902B and on the edges and portions of the sidewalls of chip 900 reaching down to be sealed with the top surface of the substrate 908.

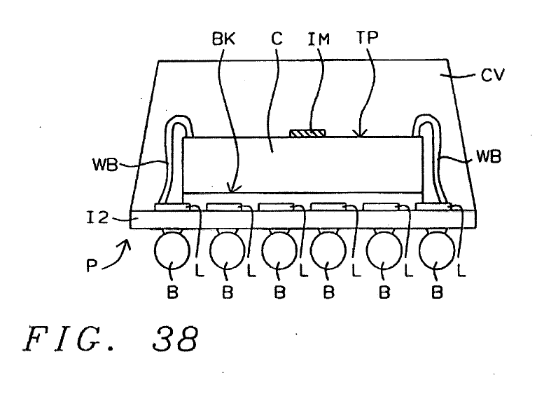

FIG. 38 shows a wire bonded CSP P with a flexible interposer I2 to which a chip C is connected by wire bonds WB. In this case the chip C is face-up so the wire bonds WB connect to the terminals on the top surface of the chip C, i.e. the face thereof. The base of the interposer I2 carries a BGA of balls B. An internal mark IM is formed on the top surface TP of the chip C. A cover CV composed of transparent material, which is optically transparent, is formed over the back surface BK on the edges and portions of the sidewalls of chip C reaching down to be sealed with the top surface of the interposer I2.

### SUMMARY

An advantage of this invention is that it prevents remarking of integrated circuit chips and distinguishes the chip function by the color of the package.

On aspect of this method is marking a chip having surfaces by forming a non-black, colored material layer over at least an exterior surface of the chip wherein the particular color indicates the identification of the chip. In more detail, the method of this invention includes marking the chip having surfaces comprises forming internal marking indicia on a marking location upon an exterior surface of the chip, and forming a non-black, optically transparent material colored with a particular color over at least the marking location on that exterior surface of the chip wherein the particular color together with the marking indicia represents identification of the chip.

In another aspect of this invention, a chip is covered with a non-black, colored material layer over at least an exterior surface of the chip wherein the particular color indicates the dentification of the chip. In more detail, the chip has internal marking indicia formed on a marking location upon an exterior surface of the chip, and a non-black, optically transparent material colored with a particular color formed over at least the marking location on that exterior surface of the chip wherein the particular color together with the marking indicia represents identification of the chip.

While this invention has been described in terms of the above specific embodiment(s), those skilled in the art will recognize that the invention can be practiced with modifications within the spirit and scope of the appended claims, i.e. that changes can be made in form and detail, without departing from the spirit and scope of the invention. Accordingly all such changes come within the purview of the present invention and the invention encompasses the subject matter of the claims which follow.

What is claimed is:

1. A silicon chip having an active-device surface at a front side of said silicon chip, comprising:
a metal contact at said front side; and
a non-black and transparent material at a back side of said silicon chip, wherein said non-black and transparent material comprises a colored additive, and wherein said front side is opposite to said back side.

2. The silicon chip of claim 1, wherein said metal contact comprises a solder.

3. The silicon chip of claim 1, wherein said non-black and transparent material comprises a polymer.

4. The silicon chip of claim 1 further comprising a silicon substrate.

5. The silicon chip of claim 1 further comprising a machine readable mark at said back side, wherein said machine readable mark is covered by said non-black and transparent material, and wherein said machine readable mark is visible through said non-black and transparent material.

6. The silicon chip of claim 1 further comprising an identity of product at said back side, wherein said identity of product is covered by said non-black and transparent material, and wherein said identity of product is visible through said non-black and transparent material.

7. The silicon chip of claim 1 further comprising an identity of manufacturer at said back side, wherein said identity of manufacturer is covered by said non-black and transparent material, and wherein said identity of manufacturer is visible through said non-black and transparent material.

8. A silicon chip having an active-device surface at a front side of said silicon chip, comprising:
a metal contact at said front side; and
a non-black and optically transmissive material at a back side of said silicon chip, wherein said non-black and optically transmissive material comprises a colored pigment, wherein said non-black and optically transmissive material is transparent, and wherein said front side is opposite to said back side.

9. The silicon chip of claim 8, wherein said metal contact comprises a solder.

10. The silicon chip of claim 8, wherein said non-black and optically transmissive material comprises a polymer.

11. The silicon chip of claim 8 further comprising a silicon substrate.

12. The silicon chip of claim 8 further comprising a machine readable mark at said back side, wherein said machine readable mark is covered by said non-black and optically transmissive material, and wherein said machine readable mark is visible through said non-black and optically transmissive material.

13. The silicon chip of claim 8 further comprising an identity of product at said back side, wherein said identity of product is covered by said non-black and optically transmissive material, and wherein said identity of product is visible through said non-black and optically transmissive material.

14. A silicon chip having an active-device surface at a front side of said silicon chip, comprising:
a metal contact at said front side; and
a non-black and colored material at a back side of said silicon chip, wherein said non-black and colored material comprises a colored pigment, wherein said non-black and colored material is transparent, and wherein said front side is opposite to said back side.

15. The silicon chip of claim 14, wherein said metal contact comprises a solder.

16. The silicon chip of claim 14, wherein said non-black and colored material comprises a polymer.

17. The silicon chip of claim 14 further comprising a silicon substrate.

18. The silicon chip of claim 14 further comprising a machine readable mark at said back side, wherein said machine readable mark is covered by said non-black and colored material, and wherein said machine readable mark is visible through said non-black and colored material.

19. The silicon chip of claim 14 further comprising an identity of product at said back side, wherein said identity of product is covered by said non-black and colored material, and wherein said identity of product is visible through said non-black and colored material.

20. The silicon chip of claim 1 further comprising an identity of manufacturer at said back side, wherein said identity of manufacturer is covered by said non-black and colored material, and wherein said identity of manufacturer is visible through said non-black and colored material.
